(19) United States
(12) Patent Application Publication
(10) Pub. No.: US 2023/0082429 A1
(43) Pub. Date: Mar. 16, 2023

(54) FORMING WAVEGUIDES AND HEAT TRANSFER ELEMENTS IN PRINTED CIRCUIT BOARDS

(71) Applicant: TTM Technologies Inc., Santa Ana, CA (US)

(72) Inventors: Niels Kirkeby, Santa Ana, CA (US); Michael Len, Santa Ana, CA (US)

(21) Appl. No.: 17/939,786

(22) Filed: Sep. 7, 2022

Related U.S. Application Data
(63) Continuation-in-part of application No. 17/162,773, filed on Jan. 29, 2021.
Application No. 17/162,773 is a continuation-in-part of application No. 17/543,512, filed on Dec. 6, 2021.
Application No. 17/543,512 is a continuation-in-part of application No. 17/225,491, filed on Apr. 8, 2021.
Application No. 17/225,491 is a continuation of application No. 16/435,174, filed on Jun. 7, 2019, now Pat. No. 10,980,127.
(60) Provisional application No. 62/968,807, filed on Jan. 31, 2020.
(60) Provisional application No. 63/123,400, filed on Dec. 9, 2020.
(60) Provisional application No. 62/814,776, filed on Mar. 6, 2019.
(60) Provisional application No. 62/837,637, filed on Apr. 23, 2019.

(51) Int. Cl. H05K 3/00; H05K 3/40; H05K 3/42

(52) U.S. Cl. CPC H05K 3/0047; H05K 3/0094; H05K 3/4038; H05K 3/42

(57) ABSTRACT

A method is provided for forming waveguides in a PCB. The method may include forming an opening in a PCB core comprising a plurality of conductive layers interleaved with a plurality of insulating layers, the opening extending from a first side of the PCB core to a second side of the PCB core. The method may also include filling the opening with metal. The method may also include forming a cavity enclosed by sidewalls by removing a first portion of the filled opening, the cavity extending from the first side of the PCB core to the second side of the PCB core. A second portion of the filled opening is a heat transfer element configured to transfer heat from the first side of the PCB core to the second side of the PCB core. The at least one waveguide is embedded within the heat transfer element and configured for transmitting signals from the first side to the second side.

### CROSS-REFERENCES TO RELATED PATENT APPLICATIONS

This patent application is a continuation-in-part of U.S. patent application Ser. No. 17/162,773, entitled “Printed Circuit Board Assemblies with Engineered Thermal Path and Methods of Manufacture,” filed on Jan. 29, 2021, which claims the benefit under 35 U.S.C. § 119(e) of U.S. Patent Application Ser. No. 62/968,807, entitled “Printed Circuit Board Assemblies with Engineered Thermal Path and Methods of Manufacture,” filed on Jan. 31, 2020, each of the foregoing applications is incorporated herein by reference in its entirety.

This patent application is also a continuation-in-part of U.S. patent application Ser. No. 17/543,512, entitled “Devices and Methods for Forming Engineered Thermal Paths of Printed Circuit Boards by use of Secondary Layers,” filed on Dec. 6, 2021, which claims the benefit under 35 U.S.C. § 119(e) of U.S. Patent Application Ser. No. 63/123,400, entitled “Devices and Methods for Forming Engineered Thermal Paths of Printed Circuit Boards by use of Secondary Layers,” filed on Dec. 9, 2020, each of the foregoing applications is incorporated herein by reference in its entirety.

This patent application is also a continuation-in-part of U.S. patent application Ser. No. 17/225,491, entitled “METHODS FOR FABRICATING PRINTED CIRCUIT BOARD ASSEMBLIES WITH HIGH DENSITY VIA ARRAY,” filed on Apr. 8, 2021, which is a continuation of U.S. patent application Ser. No. 16/435,174, entitled “METHODS FOR FABRICATING PRINTED CIRCUIT BOARD ASSEMBLIES WITH HIGH DENSITY VIA ARRAY,” filed on Jun. 7, 2019, which claims the benefit under 35 U.S.C. § 119(e) of U.S. Patent Application Ser. No. 62/814,776, entitled “METHODS FOR FABRICATING PRINTED CIRCUIT BOARD ASSEMBLIES WITH HIGH DENSITY VIA ARRAY,” filed on Mar. 6, 2019, and also claims the benefit under 35 U.S.C. § 119(e) of U.S. Patent Application Ser. No. 62/837,637, entitled “METHODS FOR FABRICATING PRINTED CIRCUIT BOARD ASSEMBLIES WITH HIGH DENSITY VIA ARRAY,” filed on Apr. 23, 2019, each of the foregoing applications is incorporated herein by reference in its entirety.

### FIELD

The disclosure is directed to designs of waveguides surrounded by a heat transfer element or a thermal path for a PCB and methods for fabricating the PCB including a combination of waveguides and heat transfer elements.

### BACKGROUND

Printed Circuit Board (PCB) Assemblies may be formed from multi-layer PCBs having Surface Mount Technology (SMT) components of integrated circuits (ICs). As SMT components and ICs require more power in combination with a continuing trend towards miniaturization, thermal management on the PCB assemblies becomes a greater challenge to manage.

PCB assemblies typically have thermal conductivity ranging from 0.25 W/mK to 3 W/mK, which results in a high thermal resistance through the PCB and consequently large temperature variations in the PCB. Typical applications for dissipation of significant power use a thermal coin. Specifically, copper coins are inserted into a PCB to help conduct the heat away from heat sources, such as ICs, die, or other components, to a heatsink underneath the PCB. In the coin manufacturing process, a hole is cut in the PCB and a thermally conductive coin, such as a copper coin, is inserted into the hole. However, the current manufacturing process for producing PCBs with copper coins is labor-intensive and expensive. As such, there exists a need for a more cost-effective method to provide coin-like thermal pathways.

Printed Circuit Board Assemblies (PCBAs) include Printed Circuit Board(s) (PCB) with Surface Mount (SMT) components soldered to the surface of the PCB(s). The SMT components dissipate power. A primary thermal path is through the PCB to a heatsink (HS). Thermal conductivity is a measure of a material's ability to conduct heat and is a material property. The thermal conductivity of typical PCB dielectric materials ranges from 0.25 W/mK to 3 W/mK, which results in a high thermal resistance through the PCB and consequently generates a large temperature delta in the PCBs. The high thermal resistance needs to be lowered to reduce the large temperature delta.

To improve the thermal path through PCBs, thermal vias may be added around the power dissipating components. A conventional way of the thermal vias is accomplished by adding Plated Through Holes (PTHs) under and around the SMT components. The method is referred to as a PTH approach. The PTHs are filled with copper, which has a thermal conductivity of about 390 W/mK which is much higher than that of the PCB, for example, 0.025 W/mk to 3 W/mk. The closer the PTHs can be positioned together, the lower the thermal resistance of the PCB would be. Based on manufacturing design rules, the standard minimum distance between drilled holes or the PTHs is one drill diameter.

When Integrated Circuits (ICs) become more power hungry, coupled with the trend of miniaturization, the thermal management on the PCB becomes a bigger challenge. The PTH approach may not reduce the thermal resistance sufficiently for applications that dissipate significant power. When the thermal vias are not sufficient to improve the thermal path, pre-fabricated copper coins may be inserted into the PCB to improve the thermal path and help conduct the heat away from heat sources, such as integrated circuits (IC), die, or SMT components, among others, to a heatsink underneath the PCB. Inserting a pre-fabricated coin is a labor-intensive manual process. In this process, a hole can be cut in the PCB and the pre-fabricated coin (e.g. commonly formed of copper) is inserted into the PCB, which is referred to as a coin approach. The manufacturing of PCBs with pre-fabricated coins is very labor-intensive and consequently expensive. Usually, the coin approach is cost-prohibitive except for use in low-volume high-performance assemblies. Additionally, there is a tolerance stack-up issue with inserted coins. Each of the coins and the PCB has a thickness with a thickness tolerance. Both the coins and the PCB have thickness variations independently from lot to lot. Another limitation of the inserted coins is that the coins have limited connection or no connection to the PCB ground. Electrical ground connections are critical for radio frequency (RF) and high-speed digital applications.

PCB may include one or more openings through the PCB forming waveguides for mmWave radars. It is desirable to have all components on one side of the PCB and have antennas and feed networks on the other side of the PCB. The trend is to feed RF signals directly from a chip on one side of the PCB, through formed waveguides in the PCB, into a metallic antenna feed-network structure. The antenna may be integrated into the feed-network structure. The waveguide is a structure that guides waves, such as electromagnetic waves, with minimal loss of energy by restricting the transmission of energy to one direction. The interior walls of the waveguide may be made of copper, silver, aluminum, or any metal that has a low electrical resistivity. For example, the interior walls are plated with metal.

In particular, a metallic antenna feed-network structure may be mounted flush to the PCB, aligned with the waveguide openings in the PCB. The metallic antenna feed-network structure may face away from the automobile or communication base station and may either form the outer part of the enclosure directly or may have a radome on top, which means that it also serves as part of a heatsink element for the system. The heatsink is a passive heat exchanger that transfers the heat generated by an electronic or a mechanical device to a fluid medium, often air or a liquid coolant, to dissipate the heat away from the device. A metallic antenna feed network mounted to the PCB furthermore spreads the heat in a plane with the PCB and thus provides a larger area for heat dissipation, a heat buffer for pulsed operation, and allows for heat transport back up through to the component side of the PCB in otherwise unused areas to a heatsink on the component side if desired. The heatsink may be used with high-power semiconductor devices such as power transistors and optoelectronics such as lasers and light-emitting diodes (LEDs), where the heat dissipation ability of the component itself is insufficient to moderate its temperature. The heatsink may be designed to maximize its surface area in contact with the cooling medium, such as the aft. Air velocity, choice of material, protrusion design, and surface treatment are factors that affect the performance of a heatsink. The heatsink attachments and thermal interface materials may also affect the die temperature of the integrated circuit and thus affect the performance and lifetime of the chip.

The conventional waveguides are normally routed into the PCB and then the routed walls are plated with a thin layer of copper (e.g., having a thickness of less than 1 mil). The conventional waveguides are separated from the coin. Also, conventionally, the waveguide in the PCB is constructed by drilling closely spaced holes into the PCB and then subsequently plating the walls of the waveguide having an oblong rounded rectangular shape. Since drill bits cannot drill square features or arbitrary features, the waveguides were limited to rectangular shapes with rounded corners.

There remains a need to address the limitations and manufacturing issues of waveguides and heat transfer elements or thermal paths for the PCBs.

### BRIEF SUMMARY

In one aspect, a method is provided for forming waveguides in a PCB. The method may include forming an opening in a PCB core comprising a plurality of conductive layers interleaved with a plurality of insulating layers, the opening extending from a first side of the PCB core to a second side of the PCB core. The method may also include filling the opening with metal. The method may also include forming a cavity enclosed by sidewalls by removing a first portion of the filled opening, the cavity extending from the first side of the PCB core to the second side of the PCB core. A second portion of the filled opening is a heat transfer element configured to transfer heat from the first side of the PCB core to the second side of the PCB core. The at least one waveguide is embedded within the heat transfer element and configured for transmitting signals from the first side to the second side.

In some variations, the cavity forms a waveguide configured to transfer signals from a first side to a second side.

In some variations, the removing of a first portion of the filled opening is done by etching.

In some variations, the sidewalls of the formed cavity are plated.

In some variations, the sidewalls are substantially perpendicular to the first side and the second side of the PCB core.

In another aspect, a method for forming waveguides in a PCB is provided.

The method may include forming an opening in a PCB core comprising a plurality of conductive layers interleaved with a plurality of insulating layers. The opening may extend from the first side of the PCB core to the second side of the PCB core. The method may also include filling the opening with metal. The method may also include forming a cavity enclosed by sidewalls perpendicular to the first side and the second side of the PCB core by etching a first portion of the filled opening. The cavity may extend from the first side of the PCB core to the second side of the PCB core to form at least one waveguide. The method may also include pattern plating an extension to the sidewalls of the cavity to form at least one lip having a shape similar to the waveguide. The method may include a lip on one side to aid in interfacing between a chip and the PCB, e.g., as a shield. The method may include a lip on the antenna feed-network structure side that may aid in interfacing between the PCB and the antenna feed-network, e.g., as mating surface and/or for shielding and/or for alignment. A second portion of the filled opening is a heat transfer element configured to transfer heat from the first side of the PCB core to the second side of the PCB core. The at least one waveguide is embedded within the heat transfer element and configured for transmitting signals from the first side to the second side.

In another aspect, a PCB may include a PCB core having a first side and a second side opposite to the first side. The PCB may also include a chip mounted on the first side of the PCB core. The PCB may also include a heat transfer element embedded in the PCB core, where the heat transfer element may include a bulk of conductive material and may extend from the first side of in the PCB core to the second side of the PCB. The PCB may also include at least one waveguide comprising a cavity enclosed by sidewalls perpendicular to the first side and the second side of the PCB core. The cavity may extend from the first side of the PCB core to the second side of the PCB core. The at least one waveguide is embedded within the heat transfer element and configured for transmitting signals from the first side to the second side or receiving signals from the second side to the first side. The heat transfer element is configured to transfer heat generated from the chip from the first side of the PCB core to the second side of the PCB core.

In a further aspect, a PCB may include a PCB core having a first side and a second side opposite to the first side. The PCB may also include a chip mounted on the first side of the PCB core. The PCB may also include a heat transfer element embedded in the PCB core, the heat transfer element comprising a bulk of conductive material and extending from the first side of the PCB core to the second side of the PCB. The PCB may also include at least one waveguide comprising a cavity enclosed by sidewalls perpendicular to the first side and the second side of the PCB core, the cavity extending from the first side of the PCB core to the second side of the PCB core. The heat transfer element comprises a first portion connecting to a second portion, the first portion being near the first side of the PCB core, and the second portion being near the second side of the PCB core and extending outward laterally from the sidewalls of the at least one waveguide such that the second portion of the heat transfer element comprises a larger heat transferring area than the first portion of the heat transfer element.

Additional embodiments and features are set forth in part in the description that follows, and will become apparent to those skilled in the art upon examination of the specification or may be learned by the practice of the disclosed subject matter. A further understanding of the nature and advantages of the disclosure may be realized by reference to the remaining portions of the specification and the drawings, which form a part of this disclosure.

### BRIEF DESCRIPTION OF THE DRAWINGS

The description will be more fully understood with reference to the following figures and data graphs, which are presented as various embodiments of the disclosure and should not be construed as a complete recitation of the scope of the disclosure, wherein:

FIG. 1A is a perspective view of a first configuration of the heat transfer element and waveguides in accordance with an embodiment of the disclosure;

FIG. 1B is a perspective view of a second configuration of the heat transfer element and waveguides in accordance with an embodiment of the disclosure;

FIG. 1C is a perspective view of a third configuration of the heat transfer element and waveguides in accordance with an embodiment of the disclosure;

FIG. 1D is a perspective view of a fourth configuration of the heat transfer element and waveguides in accordance with an embodiment of the disclosure;

FIG. 1E is a perspective view of a fifth configuration of the heat transfer element and waveguides in accordance with an embodiment of the disclosure;

FIG. 2A illustrates a perspective view of a PCB core in accordance with an embodiment of the disclosure;

FIG. 2B illustrates a perspective view of the PCB core of FIG. 2A with an opening formed in accordance with an embodiment of the disclosure;

FIG. 2C illustrates a perspective view of the opening of FIG. 2B filled in the PCB core in accordance with an embodiment of the disclosure;

FIG. 2D illustrates a perspective view of outer layers added to the PCB core of FIG. 2C in accordance with an embodiment of the disclosure;

FIG. 2E illustrates a perspective view of waveguides formed in the PCB core including the outer layers of FIG. 2D in accordance with an embodiment of the disclosure;

FIG. 2F illustrates a sectional view of lips added to the PCB core including waveguides of FIG. 2E in accordance with an embodiment of the disclosure;

FIG. 3A is a cross-sectional view of a PCB with unfilled vias in accordance with an embodiment of the prior art;

FIG. 3B is a cross-sectional view of a PCB with filled vias in accordance with an embodiment of the prior art;

FIG. 3C is a cross-sectional view of a PCB with a press-fit coin in accordance with an embodiment of the disclosure;

FIG. 3D is a cross-sectional view of a PCB with an embedded coin in accordance with an embodiment of the disclosure;

FIG. 3E is a cross-sectional view of a PCB including the plated thermal path in accordance with an embodiment of the disclosure;

FIG. 3F is a cross-sectional view of a PCB including plated thermal path and pattern plate lip in accordance with an embodiment of the disclosure;

FIG. 4A is a top view of a PCB including drilled waveguides and unfilled standard offset through-vias in accordance with the prior art, having a copper thermal cross-section of 3.1 mm2;

FIG. 4B is a top view example of a PCB including drilled waveguides and Cu-filled standard offset through-vias in accordance with the prior art, having a copper thermal cross-section of 3.4 mm2;

FIG. 4C is a top view example of a PCB including drilled waveguides and Cu-filled Via In Pad Plated Over (VIPPO) through-vias having a first size in accordance with the prior art, having a copper thermal cross-section of 9.8 mm2;

FIG. 4D is a top view example of a PCB including drilled waveguides and Cu-filled Vippo through-vias having a second size in accordance with the prior art, having a copper thermal cross-section of 11 mm2;

FIG. 4E is a top view of a PCB including a first configuration of etched and plated waveguides with a small area of heat transfer element in accordance with an embodiment of the disclosure, having a copper thermal cross-section of 24.9 mm2;

FIG. 4F is a top view of a PCB including a second configuration of etched and plated waveguides with a large area of heat transfer element in accordance with an embodiment of the disclosure, having a copper thermal cross-section of 79.3 mm2; and

FIG. 5 illustrates a top view of a PCB including waveguides of various shapes in accordance with an embodiment of the disclosure.

FIG. 6A illustrates an example of a rectangular shape of the waveguide opening in accordance with an embodiment of the disclosure;

FIG. 6B illustrates an example of a mechanical approximation to a rectangular shape with four corners in accordance with an embodiment of the disclosure;

FIG. 6C illustrates an example of a mechanical approximation to a rectangular shape without four corners in accordance with an embodiment of the disclosure;

FIG. 6D illustrates an example of an emulated rectangle with three overlapping holes in accordance with an embodiment of the disclosure;

FIG. 6E illustrates an example of an emulated rectangle with four overlapping holes in accordance with an embodiment of the disclosure;

FIG. 6F illustrates an example of an emulated rectangle with twelve overlapping holes in accordance with an embodiment of the disclosure; and

FIG. 7 illustrates the performance of the different shapes of the waveguide opening of FIGS. 6A-6F in accordance with an embodiment of the disclosure.

### DETAILED DESCRIPTION

The disclosure may be understood by reference to the following detailed description, taken in conjunction with the drawings as described below. It is noted that, for purposes of illustrative clarity, certain elements in various drawings may not be drawn to scale.

The first conventional design includes a heat-transferring element on the PCB away from a waveguide formed in the PCB. The first conventional method mechanically forms an opening in the PCB substantially underneath an excitation from a monolithic microwave integrated circuit (MMIC). The mechanically formed opening is plated to have metallic walls and function as a waveguide.

The first conventional design and method have two main limitations. First, the drilled and plated waveguides cannot form the desirable rectangular shapes, thus introducing increased insertion losses or alternatively requiring a larger area for the same performance Second, the plated walls of the waveguides may be thin and may limit the heat transferring capability. Even with the addition of thermal vias or through-vias, the heat transferring capability remains low from the chip on one side of the PCB to the antenna mounted on the opposite side of the PCB.

Alternatively, a second conventional method routes the signals in or on the PCB to a location away from the heat transfer element, and then the signals are brought to the other side via a waveguide transition through the dielectric material of the PCB, which may cause substantial additional losses compared to the first conventional method.

The disclosed technology solves the problems of conventional systems by providing a design that combines the heat transfer and transition of millimeter-wave signals from one side of a PCB to the other side of the PCB. The design implements a waveguide via or a waveguide directly into a heat transfer coin or a fully plated heat transfer element. The disclosed technology allows simultaneously maintaining both thermal resistance and electromagnetic signal losses to a minimum. The thermal resistance remains low when the heat transfer from one side of the PCB to the opposite side of the PCB is efficient. The disclosed technology facilitates co-location of heat transfer and mmWave signal transition from one side to the other side of a PCB, which is different from the conventional technology in which the heat transfer is separated from the signal transfer.

The disclosed technology solves the processing problem with rounded corners of the waveguides by etching the waveguides in the heat transfer element rather than mechanically drilling the waveguide or routing, such that waveguides can have any arbitrary cross-sections. In particular, the disclosed technology etches the waveguides into the heat transfer element in the PCB. The heat transfer element may be a copper coin or preferably a plated heat transfer element. The heat transfer element is also referred to as a thermal path.

The etching method allows the formation of waveguides of any arbitrary shapes. For example, rectangular waveguides can be formed in the plated heat transfer element by etching. The rectangular waveguides can avoid the formation of higher-order modes that can lead to losses. And the rectangular waveguides can avoid the formation of circularly polarized wave transmission, which can be an issue in the antenna radiation pattern formation. In addition, arbitrary shapes can be introduced to enhance energy transfer from a source into the waveguide or to further suppress unwanted modes or limit the frequency range.

In some aspects, the disclosed technology may be used for automotive radars and 5G and 6G millimeter-wave applications, and military radars and guidance products. For example, the disclosed technology may be used in 5G and 6G technologies, which use mmWave and sub-Tera Hz signals, or mmWave and sub-Tera Hertz waveguide antennas.

Plated heat transfer element can be used to transfer heat from one side of the PCB 102 to an opposite side of the PCB 102. The plated heat transfer element allows more flexibility in signal routing. Plated heat transfer element also allows chips to be designed to optimize the heat transfer element, waveguide locations, and waveguide pitch. The plated heat transfer element also allows having different shapes at the interface to chip versus heat transfer elements depending on the needs of heat spreading and signal routing.

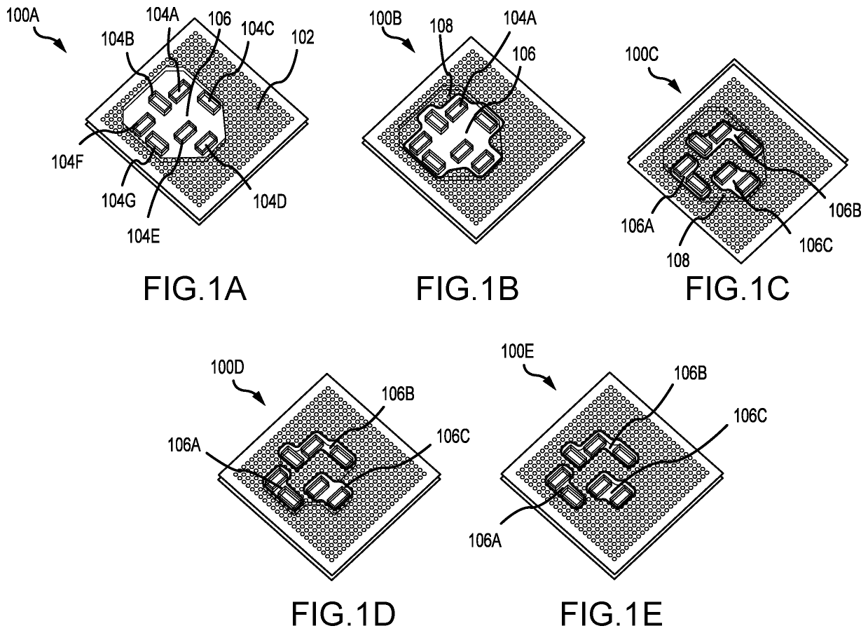

FIG. 1A is a perspective view of a first configuration of the heat transfer element and waveguides in accordance with an embodiment of the disclosure. As illustrated in FIG. 1A, a first configuration 100A includes a PCB 102, a heat transfer element 106, and multiple waveguides 104A-G embedded within the heat transfer element 106. The heat transfer element 106 with waveguides of FIG. 1A extends from the bottom to the top of the PCB in its entire area and represents a maximum heatsinking capability where a chip on the top of the PCB 102 can interface to the full areas and a heatsink at the bottom can interface to the full area.

FIG. 1B is a perspective view of a second configuration of the heat transfer element and waveguides in accordance with an embodiment of the disclosure. As illustrated in FIG. 1B, a second configuration 100B includes the PCB 102, the heat transfer element 106, and multiple waveguides 104A-G embedded within the heat transfer element 106. A first part of the heat transfer element 106 with waveguides of FIG. 1B extends from the bottom to the top of the PCB, while a second part of the heat transfer element 106, having the same area as the heat transfer element of the first configuration extends from the bottom of the PCB 102 to a layer below the top of the PCB 102. The second part of the heat transfer element functions to transfer heat down towards the bottom while also spreading the heat to a larger interface area to a subsequent heat sink at the bottom of the PCB. The second configuration 100B includes circuitry 108 that is used to route signals. The circuitry 108 is on the top of the second part of the heat transfer element 106. The circuitry 108 may be on the top of the PCB 102 or a buried layer not occupied by the first part of the heat transfer element 106. The second configuration 100B has a reduced area for a chip on the top of the PCB to interface to the heat transfer element over that of the first configuration, but the interface area to a heatsink at the bottom of the PCB is the same.

FIG. 1C is a perspective view of a third configuration of the heat transfer element and waveguides in accordance with an embodiment of the disclosure. As illustrated in FIG. 1C, a third configuration 100C includes the PCB 102, and multiple waveguides 104A-G. The third configuration 100C includes three sections of a first part of the heat transfer element with waveguides 108 extending from the bottom to the top of the PCB. The third configuration 100C includes the same second part of the heat transfer element as the second configuration 100B, extending from the bottom to a layer below the top of the PCB, The third configuration 100C includes the three small heat transfer element sections 106A, 106B, and 106C with waveguides that are separated from each other. The total area of the heat transfer elements 106A, 106B, and 106C is smaller than the area of the heat transfer element 106 in the first two configures 100A and 100B. The third configuration 100C also includes circuitry 108 that is used to route signals. This third configuration 100C provides better signal routing than the first two configurations 100A and 100B but is less efficient in heat transfer than the first two configurations 100A and 100B due to the smaller area for heat transfer. However, the area between the heat transfer elements allows additional flexibility in signal routing. The third configuration 100C has a further reduced interface area between a chip at the top of the PCB compared to the second configuration 100B but has the same interface area to a heat sink at the bottom of the PCB.

FIG. 1D is a perspective view of a fourth configuration of the heat transfer element and waveguides in accordance with an embodiment of the disclosure. A fourth configuration 100D illustrates the third configuration but with the second part of the heat transfer element being reduced to a minimal area that can encapsulate all three sections of the first part, e.g. 106A, 106B, and 106C. The total area of the heat transfer elements 106A, 106B, and 106C is the same as that in the third configuration. This fourth configuration 100D provides more signal routing than the third configuration 100C in the regions outside the boundary of the heat transfer elements. The second part has the same interface area to a chip on the top of the PCB as the third configuration but has less interface area to an external heatsink at the bottom of the PCB.

FIG. 1E is a perspective view of a fifth configuration of the heat transfer element and waveguides in accordance with an embodiment of the disclosure. As illustrated in FIG. 1E, a fifth configuration 100E includes the PCB 102, and multiple waveguides 104A-G. The fifth configuration 100E includes three small heat transfer elements 106A, 106B, and 106C that are separated from each other, similar to the third and fourth configurations 100C and 100D. The fifth configuration 100E does not have a second part to the heat transfer element. The total area of the heat transfer elements 106A, 106B, and 106C is the same as that in the third and fourth configurations 100C and 100D but is smaller than the area of the heat transfer elements 106 in the first two configurations 100A and 100B. The fifth configuration 100E does not include any outer circuitry that is used to route signals. The fifth configuration 100E provides less heat transfer than the first two configurations 100A and 100B. The fifth configuration 100E has the same interface area between the heat transfer element and a chip at the top of the PCB as the third and fourth configurations 100C and 100D, but the interface area to a heatsink at the bottom is further reduced over that of the fourth configuration 100D. The fifth configuration 100E has the most signal routing flexibility. The first and second configurations 100A and 100B may be realized with either a coin or plated heat transfer element while the configurations 100C-E are preferably made with a plated heat transfer element.

As shown above, the first configuration of the PCB assembly 100A has the most heat transfer due to that the area of the heat transfer element 106 is the largest among all the configurations 100A-E. In contrast, the fifth configuration of the PCB assembly 100C provides the most routing among all the configurations of the PCB assembly. The second configuration of the PCB assembly 100B has the second-largest heat transfer due to the larger area of the heat transfer element 106A than the third, fourth, and fifth configurations 100C, 100D, and 100E. The third configuration illustrates a good compromise between heat transferring capability and signal routing when considering the addition of a heatsink to the bottom of the PCB using traditional thermal greases.

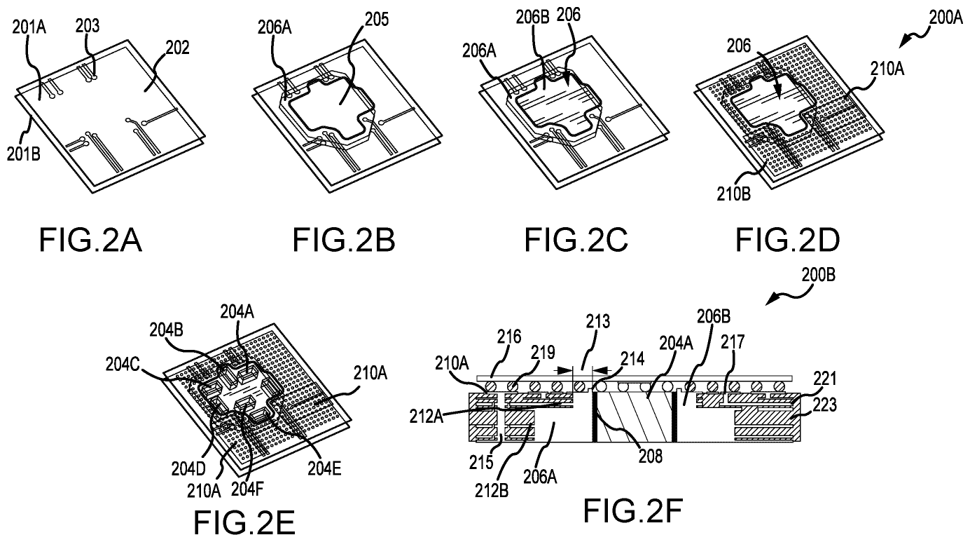

FIGS. 2A-2G illustrate schematically the method of building a PCB including one waveguide and one heat transfer element in various steps. FIG. 2A illustrates a perspective view of a PCB core in accordance with an embodiment of the disclosure. As illustrated in FIG. 2A, a PCB core 202 includes a top side 201A and a bottom side 201B. The PCB core 202 may also include circuitry 203 between the top side 201A and the bottom side 201B. The PCB core 202 may include multiple layers stacked together, which are illustrated in the sectional view of FIG. 2F.

FIG. 2B illustrates a perspective view of the PCB core of FIG. 2A with an opening formed in accordance with an embodiment of the disclosure. As illustrated in FIG. 2B, an opening 205 is formed by milling to remove a portion of the PCB core 202. The portion of the PCB core may be removed from the top 201A to the bottom 201B corresponding with the first configuration of FIG. 1A. Alternatively, the milling may be done in parts where a second part 206A is removed from the bottom 201B to a layer below the top 201A and a first part is removed from the bottom 201B to the top 201A. The bottom portion 206A is larger than the opening 205.

FIG. 2C illustrates a perspective view of the opening of FIG. 2B filled in the PCB core in accordance with an embodiment of the disclosure. As illustrated in FIG. 2C, the opening 205 and the bottom portion 206A may be filled with a conductive material, such as a metal, to form a heat transfer element 206. In one embodiment, the heat transfer element 206 may be formed by plating. In another embodiment, the heat transfer element 206 may be formed by a coin approach, such as a copper coin. The coin may be attached to an opening of the PCB core 202. If there are any gaps between the coin and the walls of the opening 205 of the PCB core 202 can be filled after the attachment of the coin.

The heat transfer element 206 may include the bottom portion 206A and a top portion 206B connecting to the top portion 206B. The side view of the heat transfer element 206 is illustrated in FIG. 2F. The bottom portion 206A has a larger area than the top portion 206B for transferring heat from the top side 201A to the bottom side 201B.

FIG. 2D illustrates a perspective view of outer layers circuitry added to the PCB core of FIG. 2C in accordance with an embodiment of the disclosure. As illustrated in FIG. 2D, outer circuitry layers are etched. As illustrated in FIG. 2D, a top outer conductive layer on the PCB core 202 is etched to form outer circuitries 210A and 210B for signal routing, which results in a PCB 200A.

FIG. 2E illustrates a perspective view of waveguides formed in the PCB core including outer circuitries of FIG. 2D in accordance with an embodiment of the disclosure. As illustrated in FIG. 2E waveguides 204A-G may be formed by etching through portions of the heat transfer element 206. The waveguides 204A-G may extend from the top side 201A of the PCB core 202 to the bottom side 201B of the PCB core 202. Then, the waveguides 204A-G may be plated with a thin layer of metal on their side walls 208. The thin metal layer may protect the waveguides against corrosion and/or improve conductivity.

FIG. 2F illustrates a sectional view of lips added to the PCB core including waveguides of FIG. 2E in accordance with an embodiment of the disclosure. This sectional view illustrates one waveguide, e.g. 204A, and one heat transfer element. A PCB 200B may optionally include lips 214, which may be pattern plated. The lips 214 may extend vertically above the top surface 201A of the PCB from the plated sidewall 208. Lips may be formed at the bottom of the PCB as well but are not illustrated here. When the signals are transmitted in the waveguide 204A, the lips 214 help maintain the transmitted signals within the waveguides and isolate the signals from other portions of the PCB core 202 and chip above the PCB. The lips 214 may also bring the waveguide 204A closer to the chip 216. The lips formed on the bottom may help interfacing to a continuing waveguide and/or antenna feed network on the bottom of the PCB. The plated waveguide 204A may also conduct heat from the top side 201A to the bottom side 201B.

As illustrated in FIG. 2F, the PCB 200B includes multiple conductive layers 221 interleaved with multiple dielectric layers 223. The conductive layers 221 may include signal traces. The PCB 200B may also include through-via 215 for conducting heat. The through-via 215 may also be referred to as thermal vias. The PCB 200B may also include blind vias 217 for connecting to internal signal traces or ground. The PCB 200B may also include through-vias 215 for signal routing to internal or external signal traces as well as ground connections. The PCB 200B may also include the outer circuitry layer 210A on the top side 201A of the PCB core 202. The outer circuitry 210A may connect to a chip 216 through conductive balls 219.

The heat from the chip 216 can be transferred from the top side 201A to the bottom side 201B through the heat transfer element 206 outside the waveguide 204A. The heat transfer element 206 may include the top portion 206B which is routed around top signal traces 212A. The top signal traces 212A may extend toward the waveguide 210A more than the bottom signal traces 212B. The bottom portion 206A of the heat transfer element 206 may extend horizontally away from the waveguide 204A more than the top portion 20AB to help spread the heat laterally.

In some aspects, the distance 213 between the vertical plated wall 208 of the waveguide 204A may be small due to the etching approach for forming the waveguide 204A without concern for use of the drilling or milling approach.

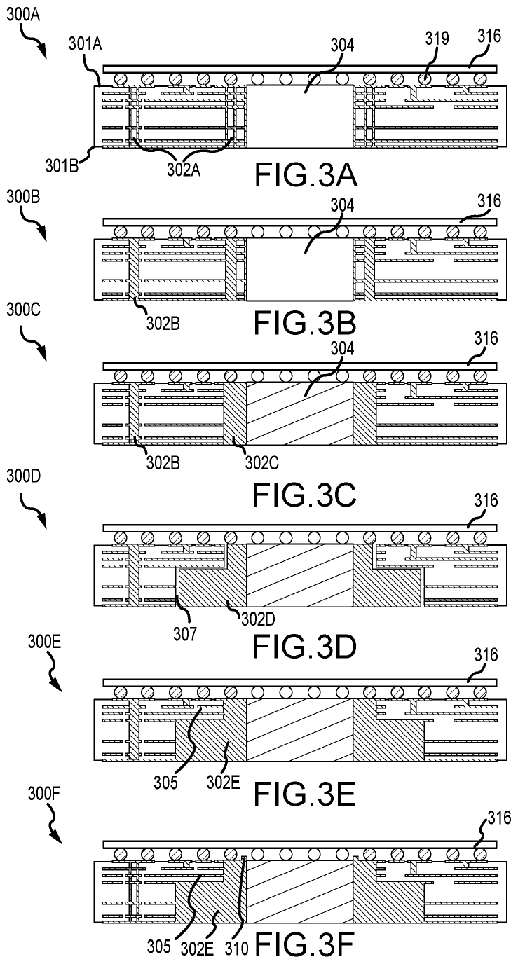

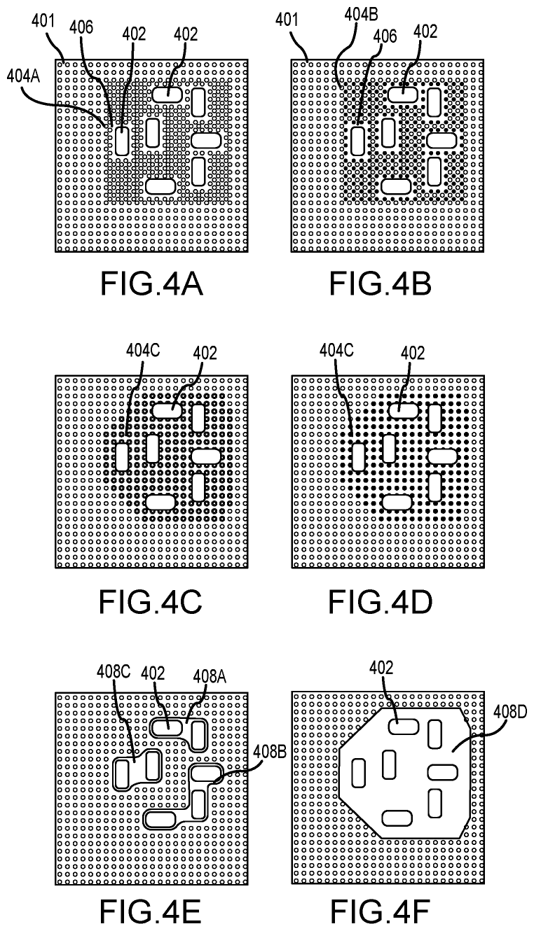

FIG. 3A is a cross-sectional view of a PCB with unfilled vias in accordance with the prior art and corresponds to FIG. 4A. As illustrated in FIG. 3A, a PCB 300A includes unfilled through-vias 302A in the PCB for transferring heat from a chip 316 on the top side 301A to the bottom side 301B. Through-vias 302A are shown both offsets, between chip pins and directly beneath chip pins (VIPPO). The PCB 300A also includes a waveguide 304 without any heat transfer element surrounding the waveguide 304. In the PCB 300A, there is full flexibility for signal routing on any layer of the PCB as long as they clear the heat transferring vias. The heat transfer is poor for this design.

FIG. 3B is a cross-sectional view of a PCB with filled vias in accordance with the prior art and corresponds to FIG. 4B. FIG. 3B is identical to FIG. 3A except that the vias for transferring heat have been copper-filled to increase the heat transferring cross-section area. The heat transfer by the filled through-vias 302B is slightly better than the unfilled through-vias 302A of the PCB 300A but may not be adequate for thermal management.

FIG. 3C is a cross-sectional view of a PCB with a press-fit coin in accordance with an embodiment of the disclosure. As illustrated in FIG. 3C, a PCB 300C includes a coin 302C press fitted into the PCB. The PCB 300C includes a heat transfer element 302C surrounding waveguide 304. The PCB 300C also includes through-vias 302B for transferring heat from the chip 316 on the top 301A to the bottom side 301B. In the PCB 300C, there is no signal routing on the top side or any other layer of the PCB in the area of the heat transfer element 302C. The PCB 300C is better than the PCB 300A and 300B due to the larger heat conduction area through the heat transfer element 302C than the filled through-vias 302B but may severely limit the ability to route signals to/from the chip.

FIG. 3D is a cross-sectional view of a PCB with an embedded coin in accordance with an embodiment of the disclosure. As illustrated in FIG. 3D, a PCB 300D includes a coin 302D embedded into the PCB. The embedded coin 302D includes a top portion that routes around the top conductive traces 305 and forms a larger lateral bottom portion than the top portion. The embedded coin may also form gaps 307 between the internal conductive layers 306D and the dielectric layers 308D. The gaps 307 make it harder to form the waveguide 304 by etching. The PCB 300D also has a larger conducting area to transfer heat than the filled through-vias 302B of the PCB 300B and thus is more efficient than the filled through-vias 302B.

FIG. 3E is a cross-sectional view of a PCB including a plated heat transfer element in accordance with an embodiment of the disclosure. As illustrated, a PCB 300E includes filled through-vias 302B and a heat transfer element 302E formed by plating and routed signal trace 305 near the top side 301A.

The plated heat transfer element approach has also a more conducting area to transfer heat than the filled through-vias and thus is more efficient than the filled through-vias.

Also, the plated heat transfer element approach may be better than the coin approach, e.g., PCB 300C or PCB 300D, for several reasons. First, the PCB 300E does not include any gaps 307 between the heat transfer element 302D and the inner conductive layers 306D or the inner dielectric layer 308D of the PCB 300D for the coin approach as illustrated in FIG. 3D. The intimate contact to inner conductive layers 306E can provide good ground and a short electric return path. The intimate contact to conductive inner layers 306E may minimize cross-coupling between stripline layers, which may help with lateral heat spreading. Second, the plated heat transfer element can be easily processed with the following PCB processes.

FIG. 3F is a cross-sectional view of a PCB including etching and plating and pattern plate lip in accordance with an embodiment of the disclosure. As illustrated in FIG. 3F, a PCB 300F including lips 310 can be formed by the plated heat transfer element approach. The lips 310 can be added by pattern plating. The lips extend the waveguide 304 up to be above the top side 301A such that the waveguide 304 becomes closer to the chip 316. Similarly, lips may be added at the bottom of the PCB to interface with a waveguide continuation structure e.g., an antenna feed network.

The plated heat transfer element with etched waveguides approach with pattern plated lips provides more copper area to transfer heat than vias and thus is more efficient than the vias 302B, as illustrated in FIG. 3B. The PCB 300F provides similar heat transferring to the PCB 300E by the plated heat transfer element approach.

It will be appreciated by those skilled in the art that many layers in the PCB may vary depending upon applications.

### Examples

The following examples are for illustration purposes only. It will be apparent to those skilled in the art that many modifications, both to materials and methods, may be practiced without departing from the scope of the disclosure.

### High Heat Transfer Efficiency and Low Cost for Etched and Plated Waveguides

The disclosed technology offers significant system performance benefits without adding much cost. In some aspects, the etched waveguides can have higher heat transfer efficiency and lower cost than the drilled waveguides with through-vias or thermal vias. Various designs illustrated in FIGS. 4A-4F are compared for heat transfer efficiencies and cost.

FIG. 4A is a top view of a PCB including drilled waveguides and plated, but unfilled standard offset through-vias in accordance with the prior art. As illustrated in FIG. 4A, waveguides 402 are surrounded by unfilled offset through-vias 404A with space 406 from the waveguides 402. Note that the through-vias 404A are offset from chip pins 401. For some PCB applications (e.g., some military and automotive applications), it is difficult to have a via directly underneath the pad for a component pin. Therefore, the offset configuration may be used. The heat-conducting area for this design is 3.1 mm2.

FIG. 4B is a top view of a PCB including drilled waveguides and Cu-filled standard offset through-vias in accordance with the prior art. FIG. 4B is the same as FIG. 4A except that the vias are copper-filled. As illustrated in FIG. 4B, multiple waveguides 402 are surrounded by filled offset through-vias 404B. Note that the through-vias 404B is offset from the chip pins 401. The heat-conducting area for this design is 9.8 mm2, thus by copper filling the vias, the heating conducting area does not improve much.

FIG. 4C is a top view of a PCB including drilled waveguides and Cu plated and dielectrically filled VIPPO through-vias having a first via size in accordance with the prior art. For many PCB applications, it is allowed to have a via directly underneath a pad for a component (VIPPO) and in those cases, more vias can be fitted in the same area since they may fit closer to the waveguides. As illustrated in FIG. 4C, multiple waveguides 402 are surrounded by Cu filed VIPPO through-vias 404C without offset. The heat-conducting area for this design is 3.4 mm2.

FIG. 4D is a top view of a PCB including drilled waveguides and Cu plated and copper-filled VIPPO through-vias having a second via size in accordance with the prior art. FIG. 4D is the same as FIG. 4C except that the vias are copper-filled. As illustrated in FIG. 4D, waveguides 402 are surrounded by WIPO through-vias 404D without offset. The heat-conducting area for this design is 11 mm2. The benefit of copper filling the vias is greater for the configurations shown in FIGS. 4C and 4D (VIPPO) than for the configurations shown in FIGS. 4A and 4B, since there are more vias to fill.

FIG. 4E is a top view of a PCB including a first configuration of etched and plated waveguides with a small area of heat transfer element in accordance with an embodiment of the disclosure. As illustrated in FIG. 4E, design 400E includes multiple etched and plated waveguides 402 embedded within multiple small heat transfer elements 408A-C, which are physically separated from each other to allow signal routing between the heat transfer elements. For example, two waveguides 402 may be embedded within a first heat transfer element 408A, three more waveguides 402 may be embedded within a second small heat transfer element 408B, and two more waveguides 402 may be embedded within a third small heat transfer element 408C. The heat-conducting area for this design is 24.9 mm2, which is more than twice that of the prior art configurations of FIG. 4A-D, but this design offers less impediment to routing of signals to/from the chip than a sea of vias.

FIG. 4F is a top view of a PCB including a second configuration of etched and plated waveguides with a large area of heat transfer element in accordance with an embodiment of the disclosure. As illustrated in FIG. 4F, design 400F includes multiple etched and plated waveguides 402 embedded within a large heat transfer element 408D, which has a larger area than the total area of the small heat transfer elements 402A-C as illustrated in FIG. 4E. The heat-conducting area for this design is 79.3 mm2, which is almost 8 times that of the prior art configurations shown in FIGS. 4A-4D, while still allowing for waveguide openings. However, this design significantly impedes the routing of signals to/from the chip.

Heat transfer efficiency and cost factors may vary with various designs. Table 1 lists the comparisons of heat transfer cross-sectional areas and cost factors of various designs. The heat-conducting area or the heat transfer cross-sectional area of the heat transfer element is largely proportional to heat transfer efficiency, depending on where the heat is produced. The cost factor is an estimate based on the number of additional processing steps and the cost associated with the additional processing steps.

TABLE 1
Comparisons of heat transfer cross-sectional
area and cost factors of various designs

| | | Area | Cost |
|---|---|---|---|
| Design | Configurations | (mm²) | Factor |
| A | Drilled waveguide with unfilled | 3.1 | 1.00 |
| | offset through-vias | | |
| B | Drilled waveguide with Cu-filled | 9.8 | 1.10 |
| | offset through-vias | | |
| C | Drilled waveguide and dielectric- | 3.4 | 1.20 |
| | filled VIPPO through-vias | | |
| D | Drilled waveguide and Cu-filled | 11.0 | 1.25 |
| | VIPPO through-vias | | |
| E | etched and plated waveguide, | 24.9 | 1.25 |
| | a small area of the heat | | |
| | transfer element | | |
| F | etched and plated waveguide, | 79.3 | 1.30 |
| | a large area of the heat | | |
| | transfer element | | |

As shown in Table 1, the heat transfer efficiency is represented by an area for transporting or transferring heat, in mm². For example, Design A as illustrated in FIG. 4A has an area of 3.1 mm² and a cost factor of 1.00, while Design B as illustrated in FIG. 4B has an area of 9.8 mm² and a cost factor of 1.10. Design C as illustrated in FIG. 4C has an area of 3.4 mm² and a cost factor of 1.20. Design D as illustrated in FIG. 4D has an area of 11.0 mm² and a cost factor of 1.25. Design E as illustrated in FIG. 4E has an area of 24.9 mm² and a cost factor of 1.25. Design F as illustrated in FIG. 4F has an area of 79.3 mm² and a cost factor of 1.30. Even the smallest plated heat transfer element of Design E is more efficient than the best via implementation of Design D. Among all the designs in Table 1, Design F has the highest area of 79.3 mm² without much cost increase from Design D.

### Shapes for Etched and Plated Waveguides

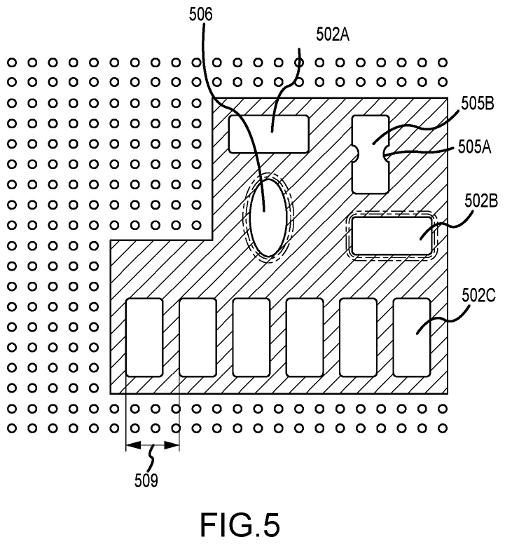

FIG. 5 illustrates a top view of a PCB including waveguides of various shapes in accordance with an embodiment of the disclosure. The etched and plated waveguides can be flexible in forming any shape. As illustrated in FIG. 5, multiple waveguides 502A-C and 506 are embedded within a heat transfer element 504. For example, waveguides 502A, 502B, and 502C may be rectangular. In some aspects, the etched waveguides can have a rectangular shape, which can have four corners at a 90° angle. The etched rectangular waveguides are configured for linear polarization and may be in TE01 mode, where TE stands for transverse electric mode.

As illustrated in FIG. 5, several rectangular waveguides 502C may be arranged linearly with a pitch 509 between two neighboring waveguides. There are no vias between the waveguides 502C.

In some aspects, the PCB may include narrower spacing between adjacent waveguides, as there are no concerns associated with mechanical machining or drilling.

In some aspects, the etched waveguides may also have a tighter pitch for the waveguides.

In some aspects, the etched waveguides 502C can have larger x and y dimensions as compared to a drilled/routed waveguide in the same boundary area or pitch and thus a lower cut-off frequency than the drilled waveguides.

Also, as illustrated in FIG. 5, a waveguide may include a necked middle portion 506A sandwiched between two outer portions 506B. The middle portion 506A is narrower than the two outer portions 506B. This example demonstrates the flexibility of forming waveguides of any shape.

Also, as illustrated in FIG. 5, a waveguide 506 may have an oval shape. In some aspects, the etched waveguides may also have an oval shape if circular polarization is desired.

In some aspects, the etched waveguides may be used for advanced waveguide functions such as coupling between two signals by forming a channel between them. Those skilled in the art will appreciate that many advanced features can be introduced if needed when etching the waveguides as opposed to machining them.

In some aspects, the etched waveguides may also have better control or restriction of higher-order modes.

When mechanically forming an opening, there are limitations in the tool sizes that can be used and costs associated with the operation. For routing out a shape of the waveguide opening, such as a rectangular shape, the smaller diameter of the bit, the slower along the path the drill bit would move, to avoid breaking, i.e., slower speed takes longer time on the router and hence increases cost. The increase in time and cost is exponential as the bit size decreases. Therefore, a typical minimum routing bit has a diameter of 0.8 mm or 32 mils.

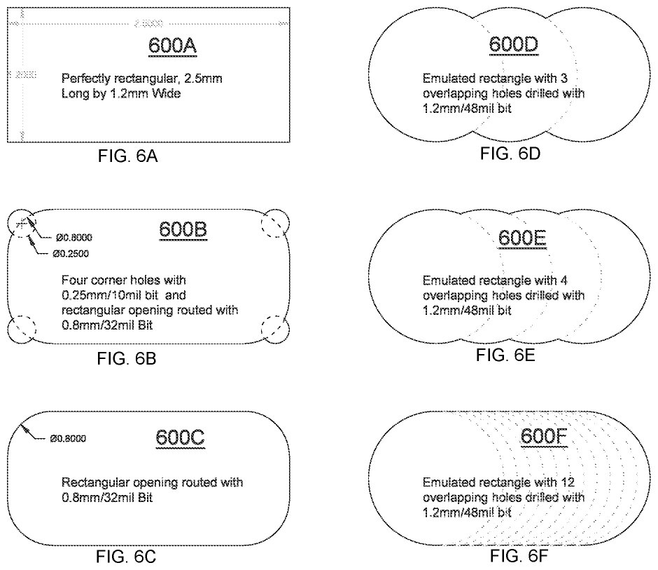

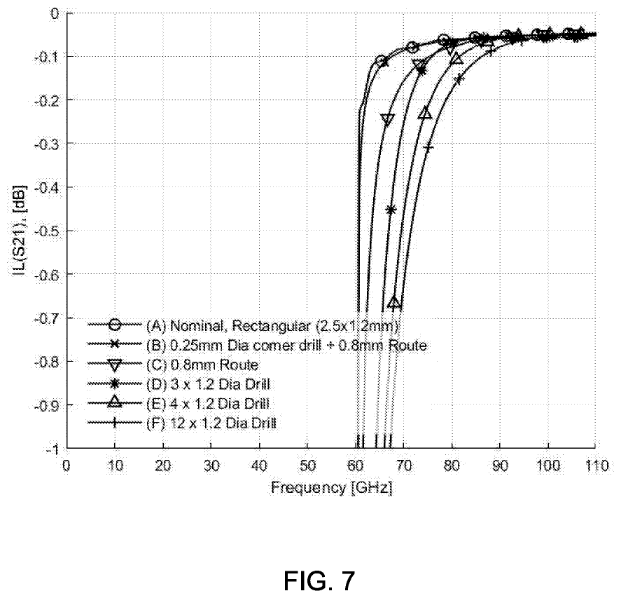

Different shapes of the waveguide opening are shown in FIGS. 6A-6F and the performances of insertion loss of these different shapes of the waveguide opening are shown in FIG. 7.

An example rectangular shape 600A of the waveguide opening is depicted in FIG. 6A. The rectangular shape 600A of the waveguide has a size of up to 2.5 mm by 1.2 mm and gives the best performance of insertion loss, as illustrated in FIG. 7.

An example mechanical approximation to a rectangular shape or rectangular approximation 600B is depicted in FIG. 6B. As shown, four holes having a diameter of 0.25 mm holes are drilled in the corners of the rectangular approximation 600B with a bit having a diameter of 0.8 mm. The rectangular approximation 600B gives the second-best performance after the rectangle 600A but is the most expensive one and can have burrs where the corners overlap the routed feature. The rectangular approximation 600B is obtained by first drilling the corners with a smaller diameter bit of 0.25 mm or 10 mil and then routing out the rest with a bit of a diameter of 0.8 mm or 32 mils. The holes need to be drilled before the routing operation. The routing out features are relatively costly and adding the extra corner holes can lead to burrs that can reduce performance.

An example of a mechanical approximation to a rectangular shape without corners or a rectangular approximation 600C is depicted in FIG. 6C. The rectangular approximation 600C is routed out with a bit having a diameter of 0.8 mm and gives the third-best performance after the rectangular shape 600A of FIG. 6A and the rectangular approximation 600B of FIG. 6B. The rectangular approximation 600C is obtained using a diameter of 0.8 mm routing bit. The approximation can be improved by drilling holes with smaller drill bits of 0.8 mm in the corners, to reduce lateral forces on the drill bit, to avoid breaking, as the rectangular approximation 600B.

A lower cost method of mechanically approximating the rectangular shape is to drill a few bigger, overlapping holes as shown in FIG. 6D (three overlapping holes), FIG. 6E (four overlapping holes), and FIG. 6F (twelve overlapping holes). While these methods are cheaper and faster, the overlapping holes create scalloping and likely undesirable burrs such that the performance is not good.

FIG. 6D illustrates an example of an emulated rectangle with three overlapping holes in accordance with an embodiment of the disclosure. An emulated rectangle 600D is obtained by drilling three holes having a diameter of 1.2 mm, which is the cheapest implementation, but only gives the fourth best performance among all the six shapes shown in FIGS. 6A-F.

FIG. 6E illustrates an example of an emulated rectangle with four overlapping holes in accordance with an embodiment of the disclosure. An emulated rectangle 600E is obtained by drilling four holes with a bit having a diameter of 1.2 mm or 48 mils.

FIG. 6F illustrates an example of an emulated rectangle with twelve overlapping holes in accordance with an embodiment of the disclosure. An emulated rectangle 600F is obtained by drilling twelve holes using a bit having a diameter of 1.2 mm.

FIG. 7 shows a comparison of the insertion loss for various methods, including the different shapes of the waveguide opening of FIGS. 6A-6F. As shown in FIG. 7, the rectangle 600A is the best followed by the routed rectangle approximation 600B with corner holes and the routed rectangle approximation 600C without corner holes.

The rectangle approximation formed by drilling overlapping holes 600D, 600E, and 600F, with three holes, four holes, and twelve holes, respectively, are worse than the rectangle 600A, the routed rectangle approximation 600B with corner holes, and the routed rectangle approximation 600C without corner holes. The rectangle approximation 600D formed by drilling overlapping holes with three holes gives the best performance among 600D, 600E, and 600F. The additional overlapping holes in emulated rectangle 600E and 600F compared to emulated rectangle 600D do not improve the performance of insertion loss.

In some variations, the waveguide can be lasered to achieve a very good approximation to the ideal shape, but this is even more costly and time-consuming than routing.

Thermal Path and/or Electrical Path

The heat transfer element is also referred to as the thermal path and/or electrical path, which may have different shapes, which can be created by changing the cavity patterns and can be different from the top side to the bottom side, or from the front side to the backside. Examples include creating a thermal path and/or an electrical path having a “T” shape, as illustrated in FIGS. 3D-3F.

In some aspects, the thermal path may be formed by adjoining top and bottom cavities.

In various aspects, the bottom cavity may be identical in size and shape to the top cavity, to form the heat transfer element 302C, as shown in FIG. 3C. Alternatively, the bottom cavity may have a different size or shape than the top cavity, to form the heat transfer element or thermal path, as shown in FIGS. 3D-3F. In various aspects, the top and bottom cavities may have any shape or cross-section, including but not limited to a circle, a square, another quadrilateral, or another polygon shape. It will be appreciated by those skilled in the art that the shape and dimensions in the cavities may vary to obtain various thermal paths and/or electrical paths. Multiple factors may affect the shape and dimensions of the cavities, including PCB dimensions in x, y, and z directions, the number of layers, the density of traces, sizes of traces, dissipated power on the top side of the PCB, the efficiency of heat transfer element on the bottom side of the PCB, among others.

In various aspects, the filling material in the cavities may be solid-plated copper. In other aspects, the filling materials can be other thermally conductive materials, including but not limited to solid silver, solid gold, and other equivalent materials with similar properties or combinations thereof.

In some variations, the signals have wavelengths that may range from 0.01 mm to 10 mm for TE01 mode.

In some variations, the signals may have frequencies of at least 1 GHz.

In some variations, the disclosed technology may be used for optical applications.

Any ranges cited herein are inclusive. The terms “substantially” and “about” used throughout this Specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Having described several embodiments, it will be recognized by those skilled in the art that various modifications, alternative constructions, and equivalents may be used without departing from the spirit of the invention. Additionally, many well-known processes and elements have not been described to avoid unnecessarily obscuring the invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the method and system, which, as a matter of language, might be said to fall therebetween.

What is claimed is:

1. A method for forming waveguides in a PCB, the method comprising:
forming an opening in a PCB core comprising a plurality of conductive layers interleaved with a plurality of insulating layers, the opening extending from a first side of the PCB core to a second side of the PCB core;
filling the opening with metal; and
forming a cavity enclosed by sidewalls by removing a first portion of the filled opening, the cavity extending from the first side of the PCB core to the second side of the PCB core,
wherein a second portion of the filled opening is a heat transfer element configured to transfer heat from the first side of the PCB core to the second side of the PCB core,
wherein the at least one waveguide is embedded within the heat transfer element and configured for transmitting signals from the first side to the second side.

2. The method of claim 1, wherein the cavity forms a waveguide configured to transfer signals from a first side to a second side.

3. The method of claim 1, wherein the removing of a first portion of the filled opening is done by etching.

4. The method of claim 1, wherein the removing of a first portion of the filled opening is done by machining, lasering, etching or any combination thereof.

5. The method of claim 1, wherein the sidewalls of the formed cavity are plated.

6. The method of claim 1, wherein the sidewalls are substantially perpendicular to the first side and the second side of the PCB core.

7. The method of claim 1, further comprising forming lips extending from the sidewalls of the cavity above the top surface of the PCB by pattern plating.

8. The method of claim 1, further comprising:
forming outer circuitry of the PCB by etching; and
applying a solder mask to the outer circuitry of the PCB.

9. The method of claim 1, wherein the filling the opening with a metal comprises plating the metal into the opening or inserting a metal coin into the opening.

10. The method of claim 1, wherein the cavity of the at least one waveguide comprises a cross-section having a rectangular shape configured for linear polarization.

11. The method of claim 1, wherein the cavity of the at least one waveguide comprises a cross-section having an oval shape configured for circular polarization.

12. The method of claim 1, wherein the metal comprises copper.

13. The method of claim 1, wherein the metal comprises a metallic nano-paste.

14. A PCB comprising:
a PCB core having a first side and a second side opposite to the first side;
a chip mounted on the first side of the PCB core;
a heat transfer element embedded in the PCB core, the heat transfer element comprising a bulk of conductive material and extending from the first side of the PCB core to the second side of the PCB; and
at least one waveguide comprising a cavity enclosed by sidewalls perpendicular to the first side and the second side of the PCB core, the cavity extending from the first side of the PCB core to the second side of the PCB core,
wherein the at least one waveguide is embedded within the heat transfer element and configured for transmitting signals from the first side to the second side or receiving signals from the second side to the first side,
wherein the heat transfer element is configured to transfer heat generated from the chip from the first side of the PCB core to the second side of the PCB core.

15. The PCB of claim 14, further comprising lips extending from the sidewalls above a top surface of the PCB from the first side of the PCB core.

16. The PCB of claim 14, wherein the cavity of the at least one waveguide comprises a cross-section having a rectangular shape configured for linear polarization.

17. The PCB of claim 14, wherein the cavity of the at least one waveguide comprises a cross-section having an oval shape configured for circular polarization.

18. The PCB of claim 14, wherein the heat transfer element comprises a metal coin embedded into the PCB core or a plated metal.

19. The PCB of claim 14, wherein the PCB comprising a plurality of conductive layers interleaved with a plurality of insulating layers.

20. The PCB of claim 14, further comprising outer circuitry on the first side of the PCB core for signal routing.

21. A PCB comprising:
a PCB core having a first side and a second side opposite to the first side;
a chip mounted on the first side of the PCB core;
a heat transfer element embedded in the PCB core, the heat transfer element comprising a bulk of conductive material and extending from the first side of the PCB core to the second side of the PCB; and
at least one waveguide comprising a cavity enclosed by sidewalls perpendicular to the first side and the second side of the PCB core, the cavity extending from the first side of the PCB core to the second side of the PCB core,
wherein the heat transfer element comprises a first portion connecting to a second portion, the first portion being near the first side of the PCB core, and the second portion being near the second side of the PCB core and extending outward laterally from the sidewalls of the at least one waveguide such that the second portion of the heat transfer element comprises a larger heat transferring area than the first portion of the heat transfer element.

22. The PCB of claim 21, wherein the at least one waveguide is embedded within the heat transfer element and configured for transmitting signals from the first side to the second side or receiving signals from the second side to the first side, wherein the heat transfer element is configured to transfer heat generated from the chip from the first side of the PCB core to the second side of the PCB core,
